(19) United States
(12) Patent Application Publication
(10) Pub. No.: US 2008/0176366 A1
(43) Pub. Date: Jul. 24, 2008

(54) Method for fabricating AIGaN/GaN-HEMT using selective regrowth

(75) Inventors: Juro Mita, Tokyo (JP); Fumihiko Toda, Tokyo (JP); Toshiharu Marui, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/984,015

(22) Filed: Nov. 13, 2007

(30) Foreign Application Priority Data
Nov. 13, 2006 (JP) 2006-306712

(51) Int. Cl. H01L 21/338

(52) U.S. Cl. 438/172; 257/E21.403

(57) ABSTRACT

A semiconductor body includes, on a substrate, a stack of buffer layer, UID-GaN layer overlying the buffer layer, and UID-AlGaN layer overlying the UID-GaN layer. On the surface of the UID-AlGaN layer, an insulation film is deposited and patterned. An n⁺-GaN layer is selectively regrown directly on a region of the surface of the semiconductor body other than the insulation film using the patterned insulation film as a mask without etching the surface of the semiconductor body. A portion of the selectively regrown n⁺-GaN layer corresponding to a region reserved for an ohmic contact electrode is defined and the ohmic contact electrode is formed on the region. An opening exposing a region reserved for a gate electrode is defined and formed within the insulation SiO₂ layer, and a gate electrode is formed in the region. An AlGaN/GaN-HEMT or MIS type of AlGaN/GaN-HEMT has lower contact resistance and uniform device characteristics.

### BACKGROUND OF THE INVENTION

1. Field of the Invention The present invention relates to a method for fabricating an AlGaN/GaN-HEMT (High-Electron Mobility Transistor) for use in, e.g. a transmitter device for a wireless or cellular phone base station or a high-breakdown voltage switching device, and in particular to a method for fabricating a selectively regrown AlGaN/GaN-HEMT having a lower resistance ohmic contact characteristic.

2. Description of the Background Art

A kind of high-electron mobility transistor (HEMT) including a Gallium Nitride (GaN) is called AlGaN/GaN-HEMT. The AlGaN/GaN-HEMT is fabricated by growing crystalline films of GaN, AlGaN, etc., in this order on an SiC (Silicon Carbide), sapphire or silicon substrate through an epitaxial crystal growth method such as metal organic chemical vapor deposition (MOCVD) or molecular beam epitaxy (MBE) and processing the epitaxial substrate thus grown.

Conventionally, inmost cases, ohmic contact electrodes such as source and drain electrodes and a gate electrode were formed directly on an epitaxial substrate to form an AlGaN/GaN-HEMT. However, that device structure often fails to provide an ohmic contact electrode with a sufficiently low contact resistance.

As a solution to the aforementioned problems, the following method using selective regrowth is disclosed in, for example, Narihiko Maeda, et al., “Al₂O₃/Si₃N₄ Insulated-Gate AlGaN/GaN Heterostructure Field-Effect Transistors with Regrown Ohmic Structure”, Technical Report of IEICE (Institute of Electronics Information and Communication Engineers of Japan), ED2004-213, MW2004-220, (2005-01), pp. 7-12. The term “selective regrowth” of as used herein is understood as a procedure in which, on an epitaxial substrate, an etching process is performed or an insulation film, etc., is deposited and patterned, and then a crystalline layer is selectively and epitaxially regrown on a region other than the insulation film on the substrate.

With reference first to FIGS. 14 to 19 showing a general process sequence for fabricating an AlGaN/GaN-HEMT using selective regrowth, the process sequence disclosed in Maeda, et al., will be described. Those figures show cross sections of the main portion of an AlGaN/GaN-HEMT processed in the important fabrication steps.

FIG. 14 is a schematic presentation of a cross section of an epitaxial substrate, sometimes referred to as a semiconductor body 110, used. As shown in the figure, to a semi-insulating (SI) SiC substrate 100, the MOCVD method is applied at a temperature of as high as 1100 to 1200 degree centigrade (° C.) (High Temperature: HT) to form a buffer layer 102 of a material such as AlN (Aluminum Nitride), as may be referred to as HT-AlN. The layer 102 acts to reduce the effect of lattice constant difference between the GaN and AlGaN layers formed on the layer 102 to allow the growth of an epitaxial layer of high crystalline quality.

Subsequently, on the layer 102 is grown an un-intentionally doped (UID) GaN electron transport layer, i.e. UID-GaN layer, 104 at a temperature of about 1070 degree centigrade. Then, a UID-AlGaN electron supply layer, referred to as UID-AlGaN layer, 108 is formed thereon. Instead of using the UID-AlGaN layer 108, an n-AlGaN layer may be formed which is doped with n-type dopant such as Si. Then, although not shown, in some cases, on the UID-AlGaN layer 108, a UID-GaN layer or n⁺-GaN layer is formed as a cap layer. In such a configuration, a two-dimensional electron gas layer 106 is formed in a region near the interface between the UID-GaN layer 104 and UID-AlGaN layer 108 on the side of the UID-GaN layer 104, due to the energy bandgap difference between GaN and AlGaN. By stacking these layers as described above, the semiconductor body 100 is prepared.

Afterwards, on one of the primary surfaces of the semiconductor body 100, which surface is called as the first principal surface 111 of the semiconductor body 110, an SiO₂ layer 112 is uniformly formed to a thickness of 100 nm, for example, by the plasma CVD (P-CVD) method, FIG. 15.

To the layer 112, photolithographic technique is applied to form a resist pattern 114 having an opening exposing a region where an n⁺-GaN layer will be selectively regrown. In this case, the region for the n⁺-GaN layer comprises at least a region where an ohmic contact electrode will be formed. Japanese patent laid-open publication No. 2005-191181 teaches that, in order to improve the uniformity in thickness of the selectively regrown layer, the region for the n⁺-GaN layer should preferably comprise the entire surface of the semiconductor body 110 except for a region between areas where a source electrode 118 and a drain electrode 120 both serving as an ohmic contact electrode will be formed as described later on.

Then, using the resist pattern 114 as a mask, the SiO₂ layer 112 is processed by wet etching with hydrofluoric acid, or dry etching such as reactive ion etching (RIE) with SF₆ gas. Afterwards, by RIE using BCl₃ gas, the semiconductor body 110 is etched deeper than the UID-AlGaN layer 108 and the two-dimensional electron gas layer 106 within the UID-GaN layer 104. After these layers are etched, a convex portion is remained which is constructed by the SiO₂ layer, UID-AlGaN layer, two-dimensional electron gas layer, and UID-GaN layer designated by 162, 158, 156, and 154, FIG. 16, respectively.

Afterwards, the resist pattern 114 is removed and, using the patterned SiO₂ layer 162 as a mask, an n⁺-GaN layer 116 is selectively regrown at a temperature of 1070 degree centigrade by the MOCVD method. In this case, the n⁺-GaN layer 116 is not grown on the SiO₂ layer 162, but only on the region, where the SiO₂ layer 162 is not present, so that the n⁺-GaN layer as a selectively regrown layer fills spaces adjacent the convex portion, as seen from FIG. 17.

Then, ions such as argon (Ar) are selectively implanted to thereby compensate for carriers in regions outside the active region of the GaN-HEMT for isolation, not shown.

Then, using photolithography technique, is formed a resist pattern, not shown, having an opening exposing a portion of the selectively regrown n⁺-GaN layer on which an ohmic contact electrode 122 will be formed. As ohmic contact material used to form a source electrode 118 and a drain electrode 120, Ti and Al are consecutively vacuum evaporated to thicknesses of 15 nm and 200 nm, respectively, and are selectively removed via a lift-off process to form the ohmic contact electrode 122. Afterwards, heat treatment is carried out in H₂ gas ambient at an appropriate temperature between 550 and 900 degree centigrade for a period of about 30 seconds to 5 minutes to provide ohmic contact between the ohmic contact electrode 122 and n⁺-GaN layer 116, FIG. 18.

Further, using photolithography technique, is formed a resist pattern, not shown, having an opening exposing a portion of the patterned SiO₂ layer 162 on which a gate electrode 124 will be formed. Then, using the resist pattern as a mask, RIE is applied by SF₆ gas to etch the SiO₂ layer 162 selectively. As gate electrode material, Ni and Au are consecutively vacuum evaporated to thicknesses of 50 nm and 500 nm, respectively, and are selectively removed via a lift-off process to form the gate electrode 124, FIG. 19. In general, the gate electrode 124 is formed closer to the source electrode 118 to reduce the source-to-gate resistance of the high-power HEMT.

Finally, on the ohmic contact electrode 122 and gate electrode 124, interconnection metals are formed as an electrode extension pad. In this way, the fabrication sequence of the AlGaN/GaN-HEMT is completed, although not shown.

As described above, in the process for fabricating a selectively-regrown AlGaN/GaN-HEMT described in the prior art example, the UID-AlGaN layer and the upper portion of the UID-GaN layer are etched out in the region where the source and drain electrodes will be formed, the selectively regrown n⁺-GaN layer 116 of high dopant concentration is formed on the region, and the ohmic contact electrode is formed on the selectively regrown layer. In this case, more electrons are allowed to flow from the ohmic contact electrode to the n⁺-GaN layer and vice versa, than the case where an ohmic contact electrode is directly formed on the UID-AlGaN layer without using selective regrowth. Consequently, this leads to a smaller contact resistance.

Narihiko Maeda, et al., report that the contact resistance was 0.3 ohm-mm and in contrast, the contact resistance was about 0.7 ohm-mm in the case where an ohmic contact electrode was directly formed on the UID-AlGaN layer in the region where the source electrode and the drain electrode will be formed without using selective-regrowth.

However, according to the method disclosed in the Maeda report, when the n⁺-GaN layer is selectively regrown on the UID-AlGaN or UID-GaN layer which has been etched by RIE, etc., it is observed in many cases that the n⁺-GaN layer does not grow homogeneously in quality and uniformly in thickness because of the deposition of impurities on the etched surface of the UID-AlGaN or UID-GaN layer, possible damage to the etched surface, and/or an indentation surface profile along the etched surface. As a result, unfortunately, sufficiently low contact resistance may not be achieved and the variations in value of the contact resistance are large. This leads to variations in property of the AlGaN/GaN-HEMT device and thus to a deterioration of the reliability of the device.

### SUMMARY OF THE INVENTION

Then, the inventors of the invention have made extensive studies in order to solve the above problems in the conventional technique. Consequently, they have found that, in order to provide a practical AlGaN/GaN-HEMT device comprising an n⁺-GaN layer which is homogeneous in quality and uniform in thickness, its UID-AlGaN or UID-GaN layer underlying the n⁺-GaN layer should not be etched but the n⁺-GaN layer should be selectively regrown directly on the UID-AlGaN layer.

The invention has been made in consideration of the conventional problems described above.

Thus, it is an object of the invention to provide a method for fabricating an AlGaN/GaN-HEMT or MIS type of AlGaN/GaN-HEMT, in which its UID-AlGaN layer is not etched but an n⁺-GaN layer is selectively regrown directly on the UID-AlGaN layer as the uppermost layer of a semiconductor body to give the AlGaN/GaN-HEMT lower contact resistance and uniform device characteristics.

According to the present invention, the method for fabricating an AlGaN/GaN-HEMT (High-Electron Mobility Transistor) comprises the steps of preparing a semiconductor body including a substrate, and a stack of a buffer layer formed on the substrate, a UID-GaN layer overlying the buffer layer and a UID-AlGaN layer overlying the UID-GaN layer; forming a pattern of insulation film on a first principal surface provided by a surface of the UID-AlGaN layer; using the pattern of insulation film as a mask to regrow selectively an n⁺-GaN layer directly on a portion of a surface of the semiconductor body other than an area covered by the insulation film without etching the surface of the semiconductor body; defining, on the selectively regrown n+-GaN layer, a region reserved for an ohmic contact electrode to be formed, and forming the ohmic contact electrode on the region; and forming, within a region defining the patterned insulation film, an opening exposing a region reserved for a gate electrode to be formed, and forming the gate electrode on the region.

Further, according to an aspect of the invention, it is preferred that the insulation film is formed as a single film made of any one of SiO₂, SiNₓ, SiOₓN_{y}, Al₂O₃ and AlN, or as a stack of two or more films of a material selected from SiO₂, SiNₓ, SiOₓN_{y}, Al₂O₃ and AlN, where x and y are a composition ratio.

According to another aspect of the invention, it is preferred that an insulation film is formed between the gate electrode and the semiconductor body.

According to the invention, a method of epitaxial crystal growth for fabricating an AlGaN/GaN-HEMT using selective regrowth may be summarized such that the UID-AlGaN and UID-GaN layers are not etched but an n⁺-GaN layer is selectively regrown directly on the uppermost surface of those layers. When comparing the method in the prior art discusses above, in which the UID-AlGaN and UID-GaN layers are etched before the n⁺-GaN layer is selectively regrown, it is clearly seen that the method of the invention is free from the problem of an indentation surface profile along the etched surface and possible damage that would otherwise caused by etching and is less susceptible to contamination of the etched surface. Accordingly, the method of the invention allows the n⁺-GaN layer selective regrowth more evenly and uniformly over the entire surface of the semiconductor wafer and reduces the occurrence of defects such as hillocks.

Further, a process of epitaxial crystal growth in accordance with the invention may be summarized as follows. That is, the UID-AlGaN layer and the UID-GaN layer are not etched but the n⁺-GaN layer is selectively regrown directly on the UID-AlGaN layer, this allows a reduction in the number of manufacturing steps and great simplification of the manufacturing process and thus improves the yield of useful devices.

Further, the electrical characteristics of devices fabricated in accordance with the invention may be summarized such that, because the surface of the semiconductor body is not etched and the n⁺-GaN layer is selectively regrown directly on the UID-AlGaN layer, the n⁺-GaN layer is uniform in thickness and homogeneous in quality, and thus the contact resistance is low between the n⁺-GaN layer and the ohmic contact electrode. This advantageously increases the performance of the HEMT device, such as maximum drain current and transconductance, etc.

Further, according to the invention, it is advantageously possible to manufacture different types of insulation films using P-CVD as well as other methods capable of forming insulative thin film layers, such as thermal CVD, ECR sputtering, and RF sputtering, etc.

Further, according to the invention, there is an additional advantage that an MIS type of AlGaN/GaN-HEMT can be fabricated. Accordingly, the maximum drain current can be achieved which is greater than that of the approach which utilizes a typical structure of HEMT. Consequently, larger output power can be expected when the HEMT is driven at a high frequency.

### BRIEF DESCRIPTION OF THE DRAWINGS

The objects and features of the present invention will become more apparent from consideration of the following detailed description taken in conjunction with the accompanying drawings in which:

FIGS. 1 through 6 show in cross-sectional views an illustrative embodiment of an AlGaN/GaN-HEMT being manufactured in a sequence of fabrication steps according to the present invention;

FIG. 7 is an explanatory plan view showing the surface pattern of the HEMT after selectively regrown according to the illustrative embodiment of the invention;

FIG. 8 explanatorily shows the stepwise profile of an HEMT after selective regrown in the prior art;

FIGS. 9 and 10 plot the FET characteristics of the AlGaN/GaN-HEMTs fabricated according to the illustrative embodiment and the prior art, respectively;

FIG. 11 shows the cross section of the MIS type of AlGaN/GaN-HEMT fabricated according to an alternative embodiment of the invention;

FIGS. 12 and 13 plot the FET characteristics of the MIS type of AlGaN/GaN-HEMTs shown in FIG. 11 and fabricated in the prior art, respectively; and

FIGS. 14 through 19 show in cross-sectional views like FIGS. 1 through 6 an AlGaN/GaN-HEMT being fabricated in a sequence of fabrication steps in the prior art.

### DESCRIPTION OF THE PREFERRED EMBODIMENTS

With reference to the drawings, the embodiments of the method for fabricating an AlGaN/GaN-HEMT according to the present invention will be described below. Further, in those figures, the shape, size and arrangement of the constitutional components are only schematically illustrated so as to allow the present invention to be understood. Further, in the following description, the numerical and other conditions to be described below are merely preferred examples. Accordingly, the present invention is not limited to the illustrative embodiments. In addition, in order to make the figures understood more easily, the figures include portions without hatching to indicate cross sections.

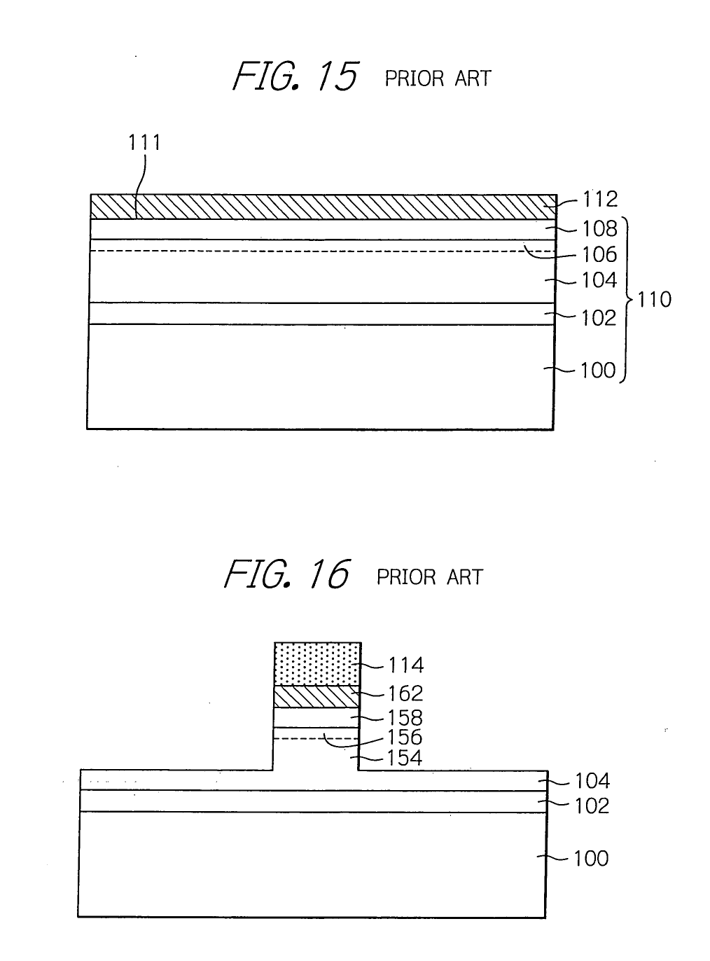

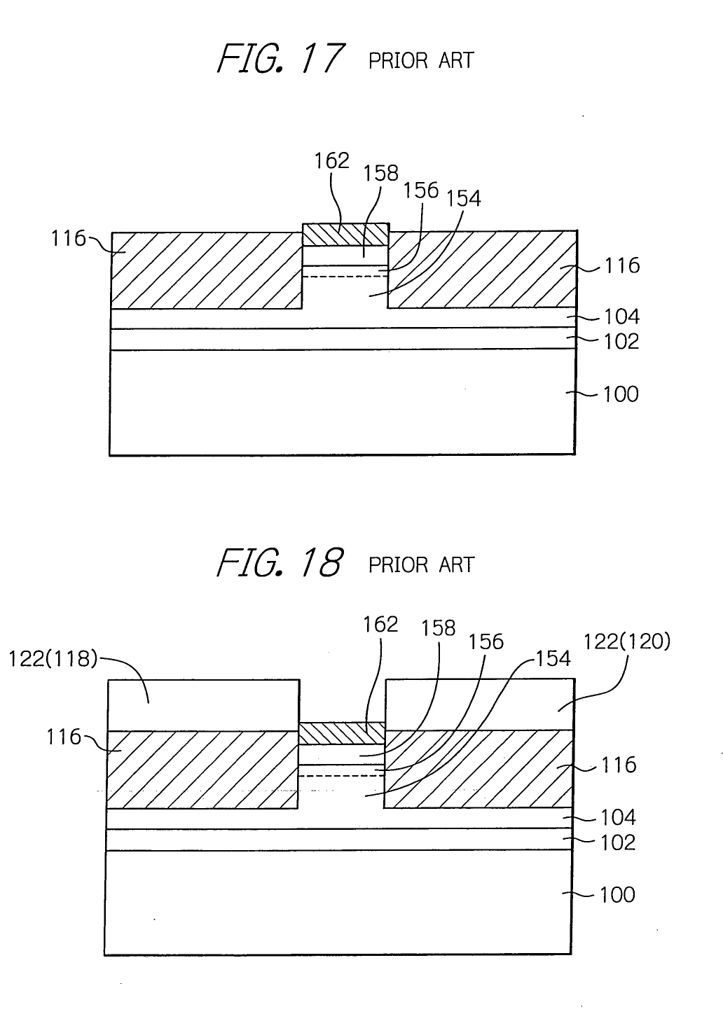

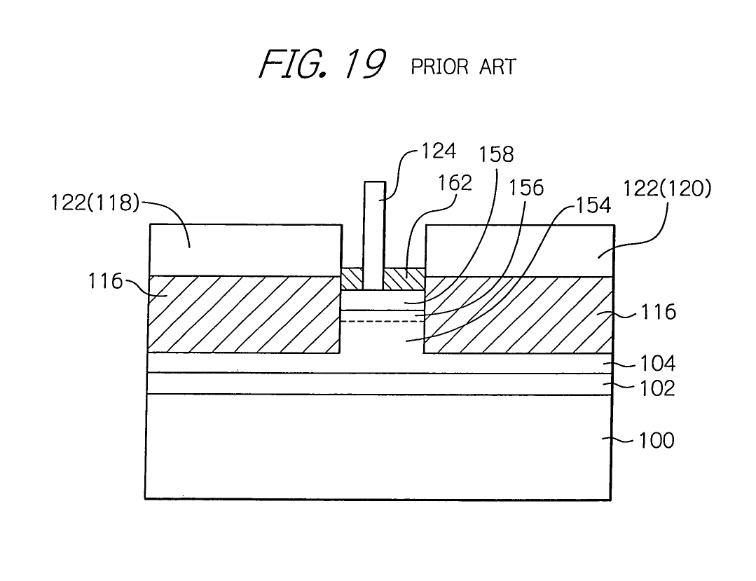

FIGS. 1 to 6 show a general process sequence of fabrication of an AlGaN/GaN-HEMT using selective regrowth in accordance with an illustrative embodiment of the invention. Those figures show the cross sections of the main portion of an AlGaN/GaN-HEMT which are being fabricated in the corresponding steps. In FIGS. 1 to 6, the elements like those of the AlGaN/GaN-HEMT shown in and described with reference to FIGS. 14 to 19 in the introductory part of the specification are designated by the same references as FIGS. 14 to 19.

FIG. 1 is a schematic presentation of a cross section of a semiconductor body 110 according to the illustrative embodiment. In the first step, to obtain a semiconductor body 110 which includes, on an SiC substrate 100, a stack of an HT-AlN buffer layer 102, a UID-GaN layer 104 overlying the HT-AlN buffer layer 102, and a UID-AlGaN layer 108 overlying the UID-GaN layer 104, the following process will be performed.

As a substrate of the semiconductor body 110, an SI-SiC substrate 100 is employed. The substrate is applied to the MOCVD method at a temperature of 1100 to 1200 degree centigrade so that an HT-AlN buffer layer 102 is grown as crystal on the substrate to a thickness of 100 nm. The HT-AlN buffer layer 102 acts to reduce the effect of lattice constant difference between the SiC substrate and the GaN or AlGaN layer laminated on the layer 102 to allow growth of an epitaxial layer of high crystalline quality. Subsequently, at a growth temperature of about 1070 degree centigrade, a UID-GaN layer 104 is deposited to a thickness of 1 μm and then a UID-AlGaN layer 108 is deposited thereon to a thickness of 23 nm, thereby forming the semiconductor body 110.

Thus,the semiconductor body 110 includes, on the SI-SiC substrate 100, a stack of HT-AlN buffer layer 102, UID-GaN layer 104, and UID-AlGaN layer 108. The uppermost layer of the semiconductor body 110 is the UID-AlGaN layer 108 and the surface of the layer 108 is referred to as a first principal surface 111 of the semiconductor body 110. In that configuration, around the interface between the UID-GaN layer 104 and UID-AlGaN layer 108 on the side of the UID-GaN layer 104, a two-dimensional electron gas layer 106 is formed due to the energy bandgap difference between GaN and AlGaN.

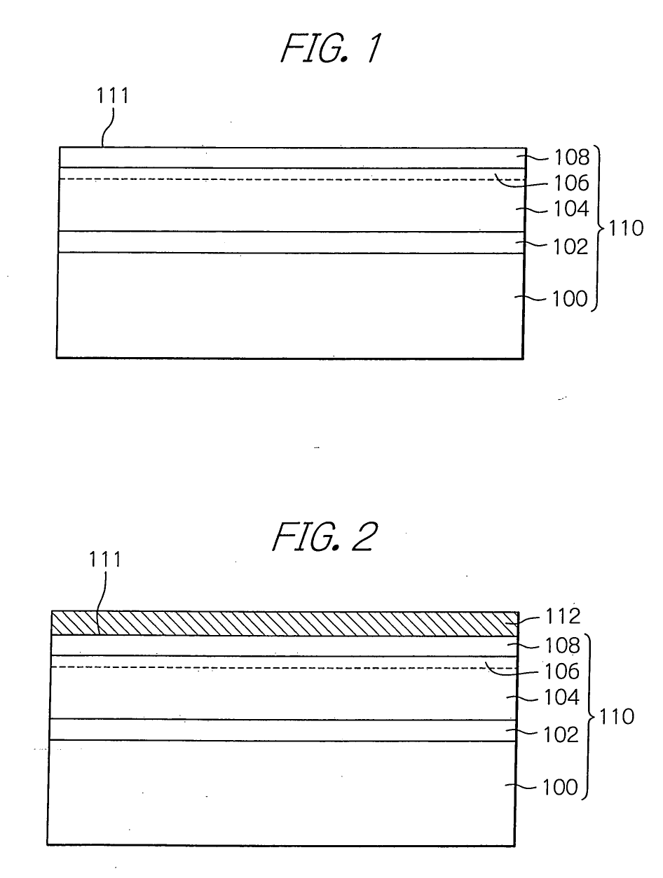

In the second step, on the first principal surface 111, an SiO₂ layer 112 functioning as an insulation film is deposited and patterned. In order to obtain the insulation film, on the first principal surface 111, the SiO₂ layer 112 is formed as an insulation film at a temperature of 300 degree centigrade by the P-CVD method to a uniform thickness of 100 nm, see FIG. 2.

In the third step, the insulation film is used as a mask not to etch the surface of the semiconductor body 110 but to regrow an n⁺-GaN layer selectively directly on a portion of the surface of the semiconductor body 110 other than that covered by the insulation film. For this purpose, in the third step, on the SiO₂ layer 112, a resist pattern 114, not shown, is formed via photolithography technique, which pattern has an opening exposing a region 113 where an n⁺-GaN layer will be selectively regrown. For convenience of description, the region 113 is the entire surface of the semiconductor body 110 except for regions between areas where a source and a drain electrode will be formed.

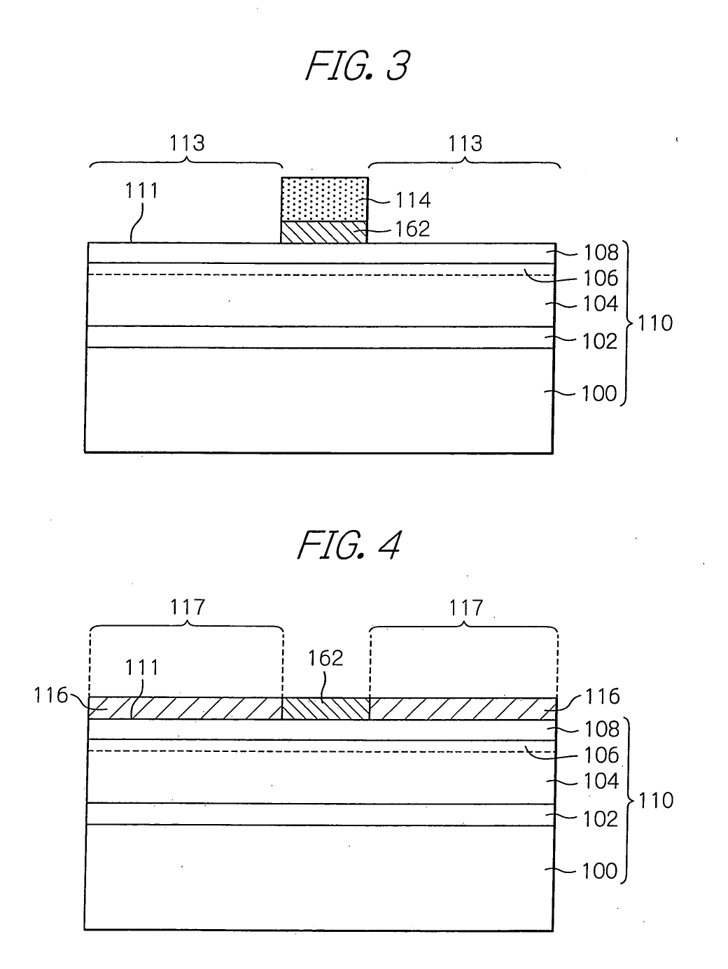

Using the resist pattern 114 as a mask, the SiO₂ layer 112 is etched by inductively coupled plasma (ICP)-RIE using SF₆ gas. The patterned SiO₂ layer is designated by 162. In this case, etching is applied only to a portion of the SiO₂ layer except for the SiO₂ layer directly under the resist pattern. After that, the portion of the principal surface 111, i.e. the surface portion of the UID-AlGaN layer 108 is exposed, which corresponds to the region 113, FIG. 3.

In the next step, the resist pattern 114 is removed, and using the patterned SiO₂ layer 162 as a mask, the MOCVD method is used at a temperature of 1070 degree centigrade to regrow the n⁺-GaN layer 116 selectively to a thickness of 100 nm. In this case, the layer 116 is not crystal grown on the layer 162, but grown only on the exposed portion of the principal surface 111 corresponding to the region 113, FIG. 4.

Then, ions such as argon Ar are selectively implanted to thereby compensate for carriers in regions outside the active region of the GaN-HEMT for isolation, not depicted.

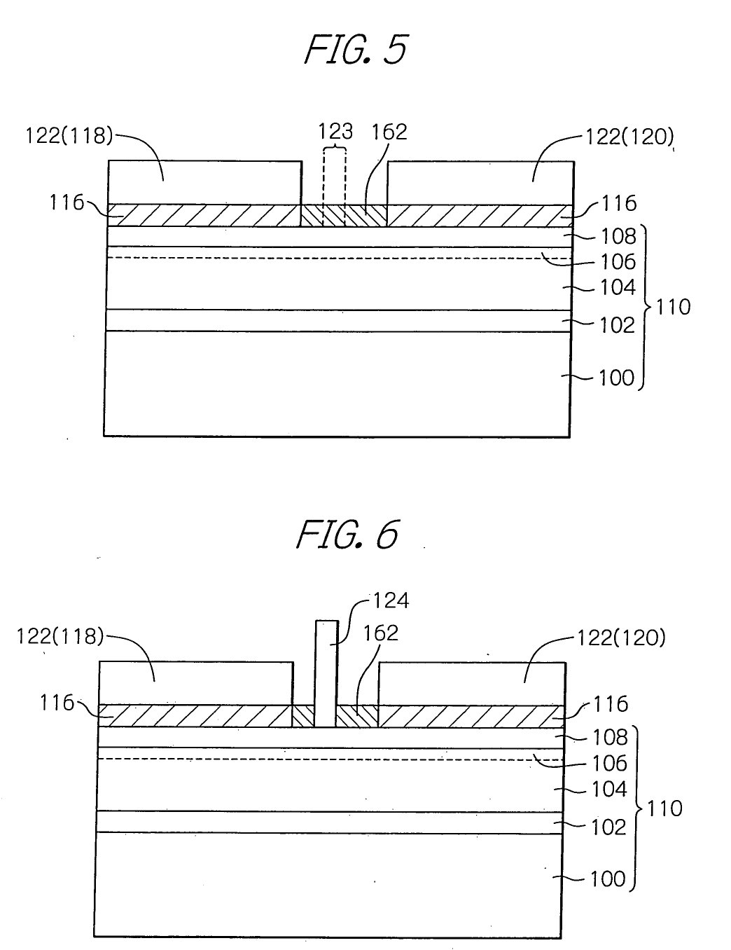

Then, in the fourth step, a portion of the layer 116 corresponding to a region 117 where an ohmic contact electrode will be formed is defined and an ohmic contact electrode 122 is formed on the region 117 reserved for the ohmic contact electrode. To this end, in the fourth step, a resist pattern, not shown, having an opening exposing the region 117 is formed using photolithography technique. Then, Ti and Al used as ohmic contact material are consecutively vacuum evaporated to thickness of 15 nm and 200 nm, respectively, to form a source electrode 118 and a drain electrode 120. In this way, on an exposed surface of the layer 116 exposed in the region 117, i.e. a surface exposed through the above resist pattern, an ohmic contact electrode 122 is formed, which comprises a two-layered structure of Ti and Al films. Then, via a lift-off process, the ohmic contact electrode 122 is formed to provide a structure shown in FIG. 5. Afterwards, the structure shown in FIG. 5 is heated in H₂ gas ambient at a temperature of 625 degree centigrade for a period of 2 minutes to provide ohmic contact between the ohmic contact electrode 122 and n⁺-GaN layer 116.

Further, in the fifth step, an opening exposing a region 123 where a gate electrode will be formed is cut in the insulation SiO₂ layer 162 and a gate electrode 124 is formed in the region 123. To do this, in the fifth step, a resist pattern, not shown, having an opening part corresponding to the region 123 of the layer 162 is formed using photolithography technique. Then, the SiO₂ layer 162 is selectively etched using the resist pattern as a mask by ICP-RIE process using SF₆ gas. In the RIE step using SF₆ gas, the UID-AlGaN layer 108 is not etched, thus only the layer 162 is etched in this case. Subsequently, Ni and Au are consecutively vacuum evaporated to thickness of 50 nm and 500 nm, respectively, and selectively removed via a lift-off procedure to form a gate electrode 124, thereby providing a structure shown in FIG. 6. In general, the gate electrode 124 is placed closer to the source electrode 118 to reduce the source-to-gate resistance of the high-power HEMT.

Finally, on the ohmic contact electrode 122 and gate electrode 124, interconnection metals are formed as an extension of contact pad. In this way, the fabrication sequence is completed of the AlGaN/GaN-HEMT, not shown, according to the illustrative embodiment of the invention.

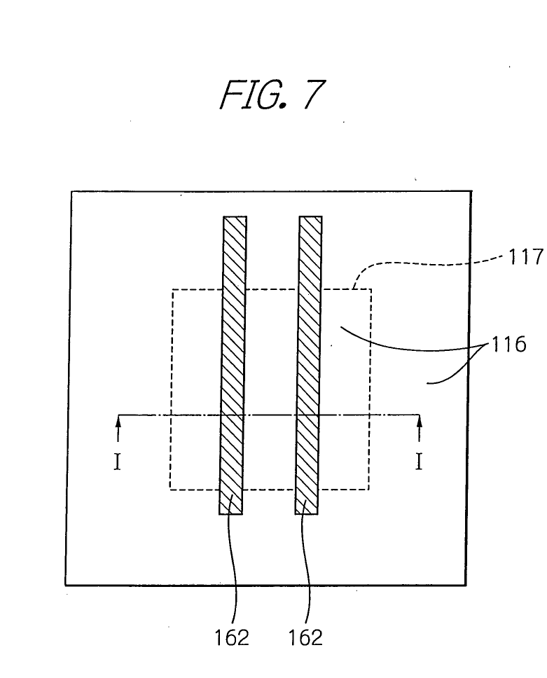

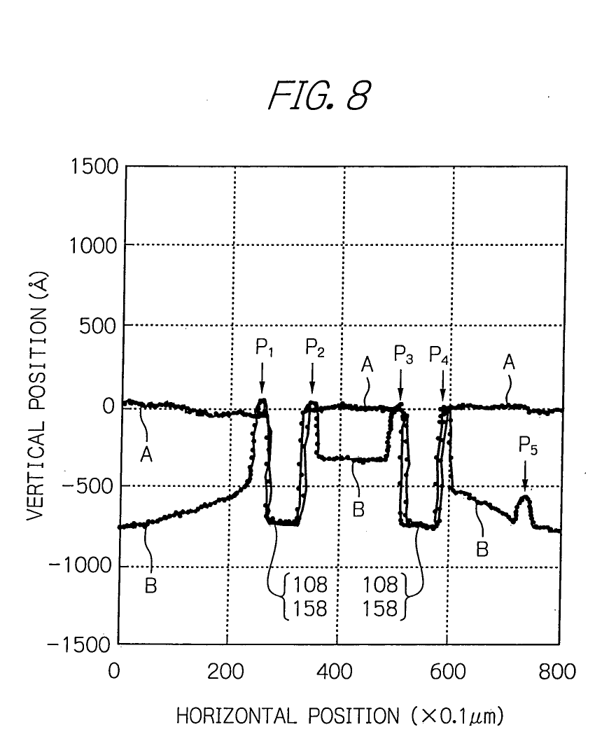

Comparing the thus formed AlGaN/GaN-HEMT of the embodiment with the AlGaN/GaN-HEMT formed on a different substrate and described in the introductory portion of the specification, the stepwise profile and surface conditions of the selectively regrown layer will be described below with reference to FIGS. 7 and 8.

A sample to be measured is a high-frequency type of dual-gate HEMT having its surface pattern illustrated in the plan view of FIG. 7. In the figure, the region 117 surrounded by a dashed line is where ohmic contact electrodes will be formed. A source electrode will be formed in the end regions and a drain electrode will be formed in the central region of the region 117. Between the central region and each of the end regions, for selective regrowth, there are a couple of SiO₂ layer 162 patterned in the form of masking strips arranged side by side. Note that in FIG. 7, hatching patterns on the SiO₂ layer 162 do not represent cross sections, but are just used to emphasize in a plan view the patterns of the layer 162. The layer 162 of masking strips is about 5 μm wide. All regions other than the regions of masking strip layer 162 are for the selective-regrowth of the n⁺-GaN layer 116.

Two different samples are prepared as described above to be measured by a surface tracing device, e.g. step measuring device, along a line I-I designated by arrows in FIG. 7 and perpendicular to the longitudinal direction of the strips of the SiO₂ layer 162. A result of the measurement is shown in FIG. 8. In FIG. 8, the abscissa axis represents a horizontal position in the unit of ×0.1 μm, and the vertical axis represents a vertical position, indicating a stepwise height difference in Angstrom with respect to the surface of the SiO₂ layer 162 before selectively regrown.

In this case, the SiO₂ layer 162 was removed from the samples before measured so as to expose the surface of the UID-AlGaN layer which is indicated by 108 in the illustrative embodiment and by 158 in the introductory part of the specification. Curve A is obtained by measuring the structure of the AlGaN/GaN-HEMT according to the illustrative embodiment and curve B is obtained by measuring the structure of the AlGaN/GaN-HEMT discussed in the introductive part of the specification.

The result shows that the AlGaN/GaN-HEMT according to the illustrative embodiment has a relatively planar surface and, except for the region where the UID-AlGaN layer 108 is exposed, includes the selectively regrown n⁺-GaN layer 116 that is grown to a substantially uniform thickness. This configuration is indispensable for manufacturing a semiconductor device and planarizing the surface of a semiconductor wafer to be processed.

With regard to the AlGaN/GaN-HEMT discussed in the introduction of the specification, the result shows that the AlGaN/GaN-HEMT is markedly uneven near the region where the UID-AlGaN layer 158 is exposed which is designated by P1, P2, P3 and P4 in FIG. 8, and that the thickness of the selectively regrown n⁺-GaN layer at the corresponding location is relatively larger. More specifically, in a selective regrowth step, around the peripheries of the mask elements of the SiO₂ layer 162, the selectively regrown layer of relatively larger thickness is formed and variations in thickness of the selectively regrown layer at those locations are large depending on the positions within the wafer, which in turn lead to large variations in electrical characteristics such as contact resistance, as will be described later. Further, a projection corresponding to the local maximum in thickness and designated by P5 was measured. The projection underlines the fact that an abnormal growth of the crystal grains of the n⁺-GaN layer occurred and the projection is referred generally to as a hillock. The unplanarity and the development of local projections are undesirable in the production of devices.

Now, comparison will be made in structure between the AlGaN/GaN-HEMT according to the illustrative embodiment and that discussed in the introductory part of the specification to get the difference of their contact resistance and FET (Field Effect Transistor) performance.

First, the contact resistance was measured using a well-known transmission line model (TLM) method. The result is that in the structure of the AlGaN/GaN-HEMT according to the illustrative embodiment, the mean value of contact resistances was 0.15 (Ωmm) in the measurement units of Rc (Ωmm) and 5.2×10⁻⁷ (Ωcm²) in the measurement units of ρc (Ωcm²) and a ratio of standard deviation σ to the mean value m, showing variations in resistance value and represented in the units of (σ/m)×100%, was 12.8% and 26.1%, respectively.

Further, the result is that in the structure of the AlGaN/GaN-HEMT discussed in the introduction of the specification, the mean value of contact resistances was 0.27 (Ωmm) in the measurement units of Rc (Ωmm) and 1.7×10⁻⁶ (Ωcm²) in the measurement units of ρc (Ωcm²) and the ratio showing variations in resistance value and represented in the units of (σ/m)×100% was 36.6% and 71.4%, respectively. The value Rc=0.27 (Ωmm) is substantially equal to the value of 0.3 (Ωmm) reported in Maeda, et al., cited earlier.

From the above results, it is noticeable that in respect of contact resistance value Rc and variation in contact resistance value Rc, the AlGaN/GaN-HEMT structure according to the illustrative embodiment is reduced down to about one half and about one third, respectively, as much as the AlGaN/GaN-HEMT structure discussed in the introductory part of the specification.

Conventionally, the selectively regrown layer is formed so as to make contact with a two-dimensional electron gas layer, after a semiconductor body is etched, as discussed on the AlGaN/GaN-HEMT in the introductory part of the specification, for example. In this case, electron carriers supplied from the ohmic contact electrode provided on the selectively regrown layer travel through the selectively regrown n⁺-GaN layer to the two-dimensional electron gas layer. By contrast, in the structure of the AlGaN/GaN-HEMT according to the illustrative embodiment, electron carriers supplied from the ohmic contact electrode travel through the selectively regrown n⁺-GaN layer and the UID-AlGaN layer to the two-dimensional electron gas layer provided as the upper portion of the UID-GaN layer.

Hitherto, it has been generally believed that the structure of the HEMT discussed in the introductory part of the specification has an advantage that more electrons are supplied to the two-dimensional electron gas layer 106. However, the above comparison between the two structures stated above reveals that larger current flows in the structure of the HEMT according to the illustrative embodiment, which will be described below.

One of the reasons therefor is that as shown in FIG. 8, the selectively regrown n⁺-GaN layer in the structure of the HEMT according to the illustrative embodiment could be grown thicker than that in the structure of the HEMT discussed in the introduction of the specification.

Further, in general, current flowing through the ohmic contact electrode is believed to flow between the opposing edges of the ohmic source and drain electrodes. In the structure of the HEMT according to the illustrative embodiment, current is allowed to flow downward from the bottom portion of an ohmic contact electrode that is relatively farther away from the edge of the ohmic contact electrode with respect to the opposing ohmic contact electrode through the two-dimensional electron gas layer below the ohmic contact electrode. In contrast, in the structure of the HEMT discussed in the introductory part, the two-dimensional electron gas layer is etched away from below the ohmic contact electrode. Accordingly, it is believed a probable cause of the difference between the results of measurement on these two samples is that no carriers flow away from the bottom portion of the ohmic contact electrode in the structure of the HEMT discussed in the introductory part.

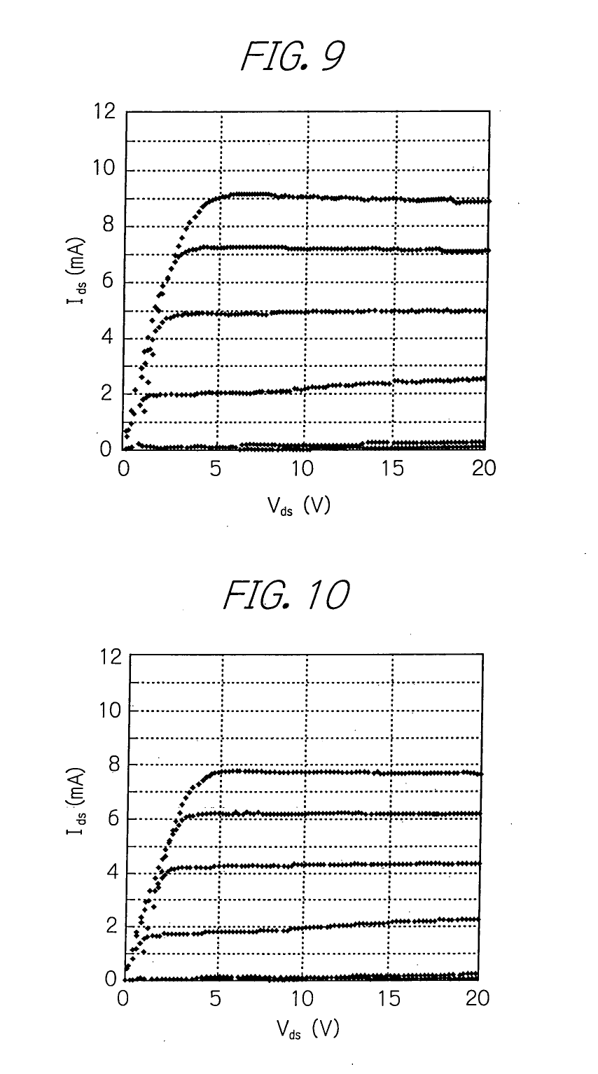

Well, comparison of the typical FET performance will be made between the structures of the AlGaN/GaN-HEMT according to the illustrative embodiment and discussed in the introductory part of the specification. In this case, the HEMT to be measured has its gate length (Lg) of 1 μm and its gate width (Wg) of 10 μm. FIGS. 9 and 10 plot the characteristic curves of the FET measured using a well-known semiconductor parameter analyzer. In both figures, the abscissa axis represents a source-drain voltage Vds of FET in the unit of volt (V) and the vertical axis represents source-drain current Ids of FET in the unit of milliampere (mA). Further, a gate voltage Vg is swept from −4V to 2V by 1V per step.

FIG. 9 shows the Ids vs Vds behavior of FET for the structure of the AlGaN/GaN-HEMT according to the illustrative embodiment and FIG. 10 shows that for the structure discussed in the introductory part of the specification. From the two characteristic curves, parameters were calculated such as maximum drain current (Ids-max at Vg of 2V), maximum transconductance (gm-max at Vds of 5V), and threshold voltages (Vth) to compare them.

With regard to the AlGaN/GaN-HEMT according to the illustrative embodiment, Ids-max (current per unit gate width: A/mm) is 0.91 A/mm, gm-max (transconductance per unit gate width: mS/mm) is 282 mS/mm, and Vth (V) is −3.00 V. With regard to the AlGaN/GaN-HEMT discussed in the introductory portion, Ids-max is 0.77 A/mm, gm-max is 247 mS/mm, and Vth. (V) is −2.99 V.

The above result indicates that the threshold voltages (Vth) in both structures are substantially the same as each other. However, the AlGaN/GaN-HEMT structure according to the illustrative embodiment is larger both in maximum drain current (Ids-max) and maximum transconductance (gm-max).

As described above, according to the method for fabricating an AlGaN/GaN-HEMT using selective-regrowth, its UID-AlGaN and UID-GaN layers are not etched and its n⁺-GaN layer is selectively regrown directly on the UID-AlGaN layer, and hence its contact resistance is greatly reduced, thereby significantly improving the performance of FET, such as maximum drain current and transconductance, etc. Further, the improvement of the direct-current (DC) characteristics of FET greatly contributes to the improvement of high-frequency and power efficiency performance.

As described so far, the invention can eliminate such drawbacks associated with the structure of the conventional AlGaN/GaN-HEMT fabricated using selective-regrowth and discussed in the introductory part of the specification as defective crystalline surface resulting from an etching process. More specifically, variations in value of ohmic contact resistance, and uneven distribution on the performance of FETs within a wafer can be eliminated.

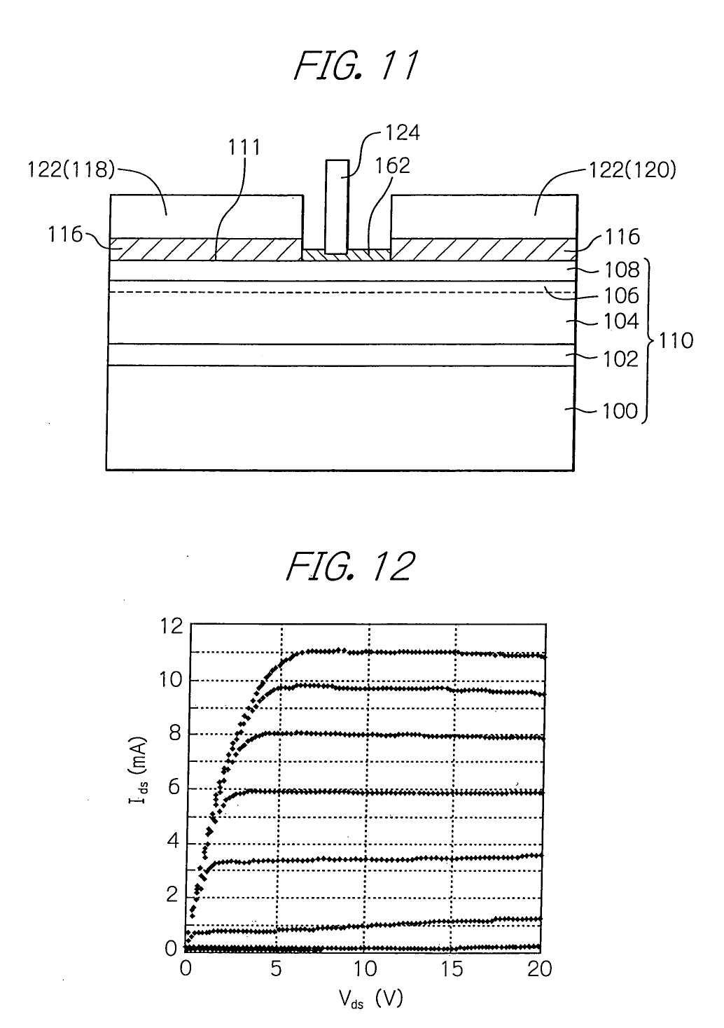

An alternative embodiment will be described which is directed to a MIS (Metal Insulator Semiconductor) type of AlGaN/GaN-HEMT fabricated using selective regrowth. FIG. 11 illustrates an alternative embodiment in a cross-sectional view of the main portion of an MIS type of AlGaN/GaN-HEMT fabricated using selective regrowth. Manufacturing steps and configuration according to this alternative embodiment may substantially be the same as the illustrative embodiment, and a description will be made only with respect to the differences from the illustrative embodiment described earlier. For convenience, like elements and components will be designated by the same reference numerals.

The configuration of SI-SiC substrate 100 and semiconductor body 110 as used herein is similar to that for the illustrative embodiment shown in and described with reference to FIGS. 1 through 6.

On a first principle surface 111 of the semiconductor body 110, an SiO₂ layer 112 is uniformly formed to a thickness of 50 nm by the P-CVD method at a temperature of as high as 300 degree centigrade. The thickness of the SiO₂ layer 112 is different from that for the embodiment shown in FIGS. 1-6.

Then, only the SiO₂ layer 112 is etched using photolithography technique and an ICP-RIE process to produce a patterned SiO₂ layer 162.

Using the remaining SiO₂ layer 162 as a mask, an n⁺-GaN layer 116 is selectively regrown by the MOCVD method. Also in this case, the n⁺-GaN layer 116 has a thickness of 100 nm.

Then, ion implantation is carried out for isolation and an ohmic contact electrode 122 is formed by a patterning process and subjected to a heat treatment to make ohmic contact.

Then, a gate electrode formation step is performed. However, that step is different from that of the embodiment shown in FIGS. 1-6. More specifically, in order to obtain an MIS FET structure, a gate structure in this alternative embodiment has an insulation film sandwiched between the gate electrode 124 and the UID-AlGaN layer 108. First, a resist pattern is formed using a photolithography technique, which resist pattern has an opening, not shown, exposing a region on the SiO₂ layer 162 where a gate electrode 124 will be formed. Then, using the resist pattern as a mask, the SiO₂ layer 162 in the region is etched by ICP-RIE using SF₆ gas. In this case, it is etched until it is a few nanometers thick on the UID-AlGaN layer 108. In this way, the SiO₂ layer 162 has a concave area and the layer in the region serves as an insulation layer of MIS structure.

As agate electrode material, Ni and Au are consecutively vacuum evaporated to thickness of 50 nm and 500 nm, respectively, and are selectively removed via a lift-off procedure to form the patterned gate electrode 124, thereby accomplishing an MIS FET having a gate structure in which the recess of the SiO₂ layer 162 is filled with the gate electrode 124, FIG. 11. In general, the gate electrode 124 is placed closer to the source electrode 118 to reduce a source-to-gate resistance.

Finally, interconnection metals are formed as an extension of contact pad on the ohmic contact electrode 122 and gate electrode 124. In this way, the fabrication sequence of the AlGaN/GaN-HEMT, not shown, is completed according to the alternative embodiment of the invention.

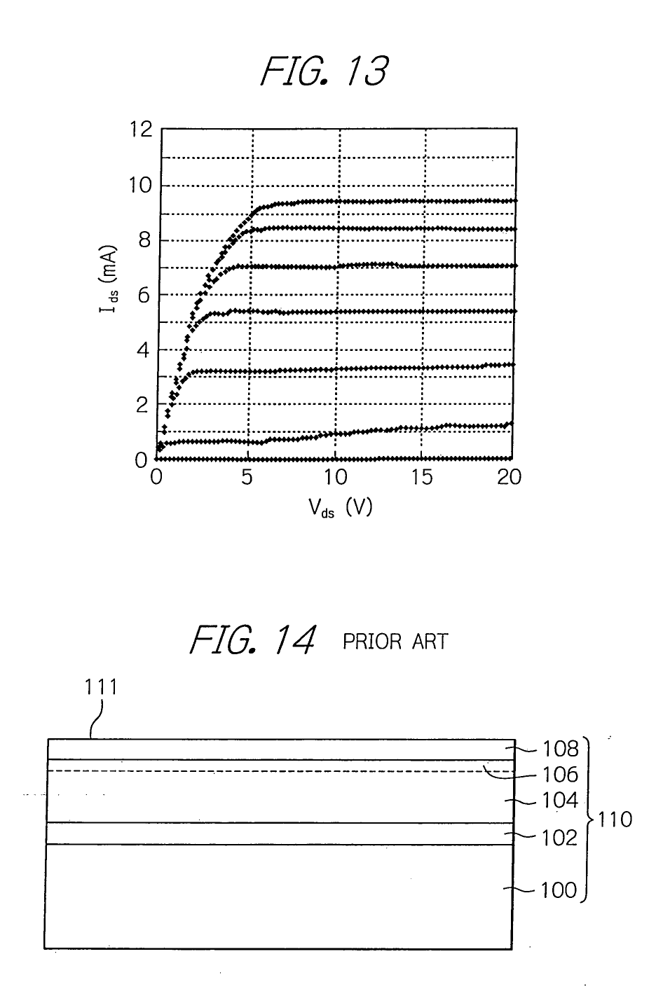

Comparison in typical FET performance will be made between the structures of the MIS type of AlGaN/GaN-HEMT according to the alternative embodiment and discussed in the introductory part of the specification. In this case, the HEMT to be measured has its gate length (Lg) of 1 μm and its gate width (Wg) of 10 μm. FIGS. 12 and 13 plot characteristic curves of the FET measured using a well-known semiconductor parameter analyzer. In FIGS. 12 and 13, the abscissa axis represents a source-drain voltage Vds of FET in the unit of V, and the vertical axis represents source-drain current Ids of FET in the unit of mA. Further, a gate voltage Vg is swept from −4V to 2V by 1V per step.

FIG. 12 shows the Ids vs Vds behavior of FET for the structure of the MIS type of AlGaN/GaN-HEMT according to the alternative embodiment and FIG. 13 shows the Ids vs Vds behavior of that discussed in the introduction of the specification. From the two characteristic curves, parameters were calculated such as maximum drain current (Ids-max at Vg of 2V), maximum transconductance (gm-max at Vds of 5V), and threshold voltages (Vth) to compare them.

With regard to the AlGaN/GaN-HEMT according to the alternative embodiment, Ids-max (current per unit gate width: A/mm) is 1.11 A/mm, gm-max (transconductance per unit gate width: mS/mm) is 258 mS/mm, and Vth (V) is −4.57 V. With regard to the AlGaN/GaN-HEMT discussed in the introductory part of the specification, Ids-max is 0.94 A/mm, gm-max is 252 mS/mm, and Vth (V) is −4.36 V.

The above result indicates that the maximum transconductance (gm-max) and the threshold voltages (Vth) in both structures are substantially the same as each other. However, the maximum drain current (Ids-max) is larger in the AlGaN/GaN-HEMT according to the alternative embodiment. Accordingly, when driven at a high frequency, the AlGaN/GaN-HEMT of the alternative embodiment can advantageously have a greater output.

Further, the AlGaN/GaN-HEMT of the alternative embodiment will be compared in FET performance to the embodiment described earlier with reference to FIGS. 9 and 10, in which the AlGaN/GaN-HEMT is not of a MIS structure and fabricated using selective-regrowth. This comparison showed that the AlGaN/GaN-HEMT having the MIS structure has higher drain current. This means adoption of the MIS structure improves the performance of the FET. Accordingly, when driven at a high frequency, the MIS type of AlGaN/GaN-HEMT can advantageously produce a greater output. With regard to the transconductance (gm), the AlGaN/GaN-HEMT having the MIS structure is smaller. This is due to the presence of an insulation film just below the gate electrode and is characteristic of a transistor having the MIS structure.

In the above-described embodiments, the examples of method for selectively regrowing use a P-CVD SiO₂ layer as a mask. The layer is not limited to that specific SiO₂ film, but may be implemented by a single insulation thin film of a material such as SiNₓ, SiOₓN_{y}, Al₂O₃, and AlN, or a multi-layered insulation film having two or more of the above insulation thin films. Further, a method for depositing the above insulation films may be implemented by other methods for forming insulation films using P-CVD as well as other types of CVDs, such as thermal CVD, etc., and sputtering, such as ECR sputtering, RF sputtering, etc.

The entire disclosure of Japanese patent application No. 2006-306712 filed on Nov. 13, 2006, including the specification, claims, accompanying drawings and abstract of the disclosure, is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. A method for fabricating an AlGaN/GaN-HEMT (High-Electron Mobility Transistor), comprising the steps of:
preparing a semiconductor body including a substrate, and a stack of a buffer layer formed on the substrate, a UID-GaN layer overlying the buffer layer and a UID-AlGaN layer overlying the UID-GaN layer;
forming a pattern of insulation film on a first principal surface provided by a surface of the UID-AlGaN layer;
using the pattern of insulation film as a mask to regrow selectively an n⁺-GaN layer directly on a portion of a surface of the semiconductor body other than an area covered by the insulation film without etching the surface of the semiconductor body;
defining, on the selectively regrown n+-GaN layer, a region reserved for an ohmic contact electrode to be formed, and forming the ohmic contact electrode on the region; and
forming, within a region defining the patterned insulation film, an opening exposing a region reserved for a gate electrode to be formed, and forming the gate electrode on the region.

2. The method in accordance with claim 1, wherein the insulation film is formed as a single film made of any one of SiO₂, SiNₓ, SiOₓN_{y}, Al₂O₃ and AlN, where x and y are a composition ratio.

3. The method in accordance with claim 1, wherein the insulation film is formed as a stack of two or more films of a material selected from SiO₂, SiNₓ, SiOₓN_{y}, Al₂O₃ and AlN, where x and y are a composition ratio.

4. The method in accordance with claim 1, wherein the insulation film is formed between the gate electrode and the semiconductor body.
